(19) United States
(12) Patent Application Publication
(10) Pub. No.: US 2016/0133444 A1
(43) Pub. Date: May 12, 2016

(54) INK COMPOSITION FOR DETECTING PLASMA TREATMENT AND INDICATOR FOR DETECTING PLASMA TREATMENT

(71) Applicant: SAKURA COLOR PRODUCTS CORPORATION, Osaka (JP)

(72) Inventors: Seisaku Oshiro, Osaka-shi (JP); Marimo Mori, Osaka-shi (JP); Keiko Nakamura, Osaka-shi (JP)

(73) Assignee: SAKURA COLOR PRODUCTS CORPORATION, Osaka-shi, Osaka (JP)

(21) Appl. No.: 14/895,835

(22) PCT Filed: May 29, 2014
(86) PCT No.: PCT/JP2014/064209

§ 371 Date: Dec. 3, 2015

(30) Foreign Application Priority Data
Jun. 4, 2013 (JP) 2013-117940
Apr. 21, 2014 (JP) 2014-087653

(51) Int. Cl. H01J 37/32; C09D 11/102; C08K 5/23; C08K 5/3417; B43K 7/00; G06K 19/06; B65D 5/42; B65D 75/52; B65D 81/20; C09D 11/02; C08K 5/053

(52) U.S. Cl. CPC H01J 37/32963; C09D 11/02; C09D 11/102; C08K 5/23; C08K 5/3417; C08K 5/053; G06K 19/06028; G06K 19/0614; B65D 5/4216; B65D 75/522; B65D 81/2084; B43K 7/00

(57) ABSTRACT

An ink composition is provided for detecting plasma treatment, the composition containing a colorant and a nonionic surfactant, wherein (1) the colorant is at least one member selected from the group consisting of anthraquinone colorants, methine colorants, azo colorants, and phthalocyanine colorants; and (2) the nonionic surfactant is at least one of the surfactants represented by formulae (I) to (V):

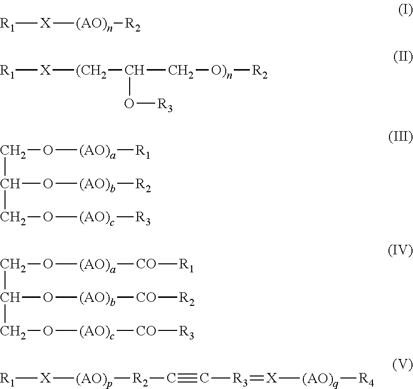

(wherein R₁, R₂, R₃, and R₄ are each independently hydrogen or a straight-chain or branched aliphatic hydrocarbon group having 1 to 30 carbon atoms; X is oxygen or an ester bond; AO is a repeating unit derived from an alkylene oxide; n is an integer of 1 to 200; the sum of a, b, and c is an integer of 3 to 200; and the sum of p and q is an integer of 0 to 20).

### TECHNICAL FIELD

The present invention relates to an ink composition for detecting plasma treatment and to an indicator for detecting plasma treatment using the composition. The plasma treatment as referred to herein means a plasma treatment using a plasma generated by applying AC voltage, pulse voltage, high-frequency waves, microwaves, etc., using a gas for generating plasma. The plasma treatment includes both reduced-pressure plasma and atmospheric-pressure plasma.

### BACKGROUND ART

Various types of equipment, instruments, etc., used in hospitals, laboratories, and the like are sterilized for disinfection and killing bacteria and fungi. Plasma sterilization treatment is known as a sterilization treatment (see, for example, “3.3.1 Sterilization Experiment Using Low-pressure Discharge Plasma” in Non-patent Literature (NPL) 1).

More specifically, plasma sterilization treatment generates plasma in an atmosphere of a gas for generating plasma and sterilizes equipment, instruments, etc., by using low-temperature gas plasma. Plasma sterilization treatment is advantageous in that the sterilization treatment can be performed at a low temperature.

Plasma treatment is used not only for sterilization treatment but also for plasma dry etching and plasma cleaning of the surface of items to be treated, such as electronic parts, in the process of manufacturing semiconductor devices.

Plasma dry etching generally comprises applying high-frequency power to electrodes disposed in a reaction chamber that is a vacuum vessel, plasmarizing a gas for generating plasma introduced in the reaction chamber, and etching a semiconductor wafer with high precision. Plasma cleaning removes metal oxides, organic substances, burrs, etc., deposited on or adhering to the surface of items to be treated, such as electronic parts, to improve bonding or wettability of solder, thus enhancing bonding strength and improving adhesion to a sealing resin and wettability.

As methods for detecting an end point of such a plasma treatment, for example, PTL 1 discloses a method for detecting an end point of plasma dry etching using an emission spectrum intensity curve obtained by a process wherein all of an emission spectrum from a gas plasma is taken into a photomultiplier with a wavelength of 300-650 nm.

PTL 2 discloses a method for detecting an end point of a plasma treatment, comprising a transmission step of changing a transmission wavelength using an incident angle changing means for changing the incident angle from a plasma light source to be monitored as a band-pass filter for selectively transmitting only a specified wavelength region; a detection step of detecting light transmitted in the transmission step with a detector; and a calculation output step of comparing and calculating the states during and before a reaction using a calculation output device comprising a wavelength converting means to which a detection output from the detector in the detection step and an angle output from the incident angle changing means in the transmission step are input to make the detected output of the transmission wavelength a value obtained without any change in the incident angle even when the incident angle is changed, and outputting the end point of the plasma treatment to an output apparatus.

These conventional end point detection methods require an emission spectrum analysis device, a calculation output device, and like devices, and also have difficulty in individually detecting the plasma-treated items. Accordingly, development has been desired for a technique that is a simple method without requiring use of a large device and that can individually detect the completion of plasma treatment of the items to be treated.

### CITATION LIST

### PTL

PTL 1: JPH6-069165A
PTL 2: JP2004-146738A

### NPL

NPL 1: Journal of Plasma and Fusion Research Vol. 83, No. 7 July 2007

### SUMMARY OF INVENTION

### Technical Problem

A primary object of the present invention is to provide an ink composition with which the completion of plasma treatment of the items to be treated can be individually detected without using a large device, and to provide and an indicator using the composition.

### Solution to Problem

The present inventors conducted extensive research to achieve the above object. As a result, they found that the object can be achieved by using an ink composition of a specific formulation, and the present invention has thus been accomplished.

Specifically, the present invention provides the following ink compositions for detecting plasma treatment and indicators for detecting plasma treatment.

1. An ink composition for detecting plasma treatment, the composition comprising a colorant and a nonionic surfactant,
(1) the colorant being at least one member selected from the group consisting of anthraquinone colorants, methine colorants, azo colorants, phthalocyanine colorants, triphenylmethane colorants, and xanthene colorants; and
(2) the nonionic surfactant being at least one of the surfactants represented by formulae (I) to (V):

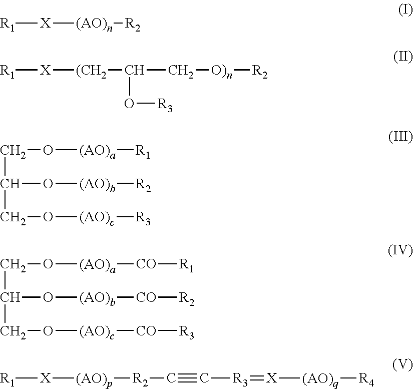

(wherein R₁, R₂, R₃, and R₄ are each independently hydrogen or a straight-chain or branched aliphatic hydrocarbon group having 1 to 30 carbon atoms; X is oxygen or an ester bond; AO is a repeating unit derived from an alkylene oxide; n is an integer of 1 to 200; the sum of a, b and c is an integer of 3 to 200; and the sum of p and q is an integer of 0 to 20).
2. The ink composition according to Item 1, further comprising at least one member selected from the group consisting of binder resins and fillers.
3. The ink composition according to Item 2, wherein the binder resins are all or partially nitrogen-containing polymers.
4. The ink composition according to Item 3, wherein the nitrogen-containing polymers are all or partially polyamide resins.
5. The ink composition according to Item 2, wherein the binder resins are all or partially phenolic resins.
6. The ink composition according to any one of Items 2 to 5, wherein the fillers are all or partially silicas.
7. The ink composition according to any one of Items 1 to 6, further comprising at least one colorant component that does not change color in a plasma treatment atmosphere.
8. An indicator for detecting plasma treatment comprising a color-changing layer formed of the ink composition according to any one of Items 1 to 7.
9. The indicator according to Item 8 comprising a non-color-changing layer that does not change color in the plasma treatment atmosphere.
10. The indicator according to Item 8 or 9, wherein the color-changing layer is in the form of a bar code.
11. The indicator according to Item 10, wherein the color-changing layer changes color in a plasma treatment environment to allow reading by a bar code reader, thus enabling plasma treatment management.
12. A plasma treatment package comprising a gas-permeable package and the indicator according to any one of Items 8 to 11 on the inner surface of the package.
13. The package according to Item 12, having a transparent window in a part of the package so as to enable the indicator to be checked from the outside.
14. A plasma treatment method comprising placing one or more items to be treated in the package according to Item 12 or 13, sealing the package containing the items to be treated, and disposing the package in the plasma treatment atmosphere.
15. The treatment method according to Item 14, wherein the package is allowed to stand in the plasma treatment atmosphere until the color-changing layer of the indicator has changed color.
16. An image drawing tool comprising the ink composition according to any one of Items 1 to 7.

The ink composition and indicator for detecting plasma treatment according to the present invention are described below in detail.

### 1. Ink Composition for Detecting Plasma Treatment

The ink composition for detecting plasma treatment (hereinafter also simply referred to as “ink composition”) contains a colorant and a nonionic surfactant. (1) The colorant is at least one member selected from the group consisting of anthraquinone colorants, methine colorants, azo colorants, and phthalocyanine colorants. (2) The nonionic surfactant is at least one of the surfactants represented by formulae (I) to (V):

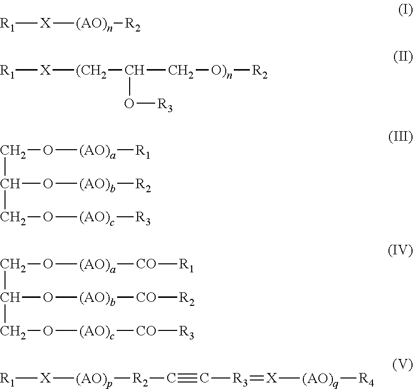

(wherein R₁, R₂, R₃, and R₄ are each independently hydrogen or a straight-chain or branched aliphatic hydrocarbon group having 1 to 30 carbon atoms; X is oxygen or an ester bond; AO is a repeating unit derived from an alkylene oxide; n is an integer of 1 to 200; the sum of a, b, and c is an integer of 3 to 200; and the sum of p and q is an integer of 0 to 20).

### Coloring Agent (Colorant)

As a coloring agent (also called a “colorant” or a “color-changing colorant”), the ink composition of the present invention contains at least one member selected from the group consisting of anthraquinone colorants, methine colorants, azo colorants, and phthalocyanine colorants.

Anthraquinone colorants may be any colorant that has anthraquinone as a basic skeleton. Known anthraquinone dispersing dyes and the like are also usable. In particular, anthraquinone colorants containing an amino group are preferable. Anthraquinone colorants containing at least one amino group selected from the group consisting of primary amino groups and secondary amino groups are more preferable. In this case, the composition may contain one or more primary amino groups and/or one or more secondary amino groups, and each of the amino groups may be of the same or different type.

Specific examples include 1,4-diaminoanthraquinone (C.I. Disperse Violet 1), 1-amino-4-hydroxy-2-methylaminoanthraquinone (C.I. Disperse Red 4), 1-amino-4-methylaminoanthraquinone (C.I. Disperse Violet 4), 1,4-diamino-2-methoxyanthraquinone (C.I. Disperse Red 11), 1-amino-2-methylanthraquinone (C.I. Disperse Orange 11), 1-amino-4-hydroxyanthraquinone (C.I. Disperse Red 15), 1,4,5,8-tetraminoanthraquinone (C.I. Disperse Blue 1), 1,4-diamino-5-nitroanthraquinone (C.I. Disperse Violet 8), and the like (color index names are in parentheses).

Other usable colorants include those known as C.I. Solvent Blue 14, C.I. Solvent Blue 35, C.I. Solvent Blue 63, C.I. Solvent Violet 13, C.I. Solvent Violet 14, C.I. Solvent Red 52, C.I. Solvent Red 114, C.I. Vat Blue 21, C.I. Vat Blue 30, C.I. Vat Violet 15, C.I. Vat Violet 17, C.I. Vat Red 19, C.I. Vat Red 28, C.I. Acid Blue 23, C.I. Acid Blue 80, C.I. Acid Violet 43, C.I. Acid Violet 48, C.I. Acid Red 81, C.I. Acid Red 83, C.I. Reactive Blue 4, C.I. Reactive Blue 19, C.I. Disperse Blue 7, and the like.

These anthraquinone colorants can be used singly or in a combination of two or more. Among these anthraquinone colorants, C.I. Disperse Blue 7, C.I. Disperse Violet 1, and the like are preferable. In the present invention, detection sensitivity can be controlled by changing the kinds (molecular structures, etc.) of such anthraquinone colorants used.

The methine colorants may be any colorant that has a methine group. Polymethine colorants, cyanine colorants, and the like are thus also included within the scope of methine colorants in the present invention. These colorants can be appropriately selected from known or commercially available methine colorants. Specific examples include C.I. Basic Red 12, C.I Basic Red 13, C.I. Basic Red 14, C.I. Basic Red 15, C.I. Basic Red 27, C.I. Basic Red 35, C.I. Basic Red 36, C.I. Basic Red 37, C.I. Basic Red 45, C.I. Basic Red 48, C.I. Basic Yellow 11, C.I. Basic Yellow 12, C.I. Basic Yellow 13, C.I. Basic Yellow 14, C.I. Basic Yellow 21, C.I. Basic Yellow 22, C.I. Basic Yellow 23, C.I. Basic Yellow 24, C.I. Basic Violet 7, C.I. Basic Violet 15, C.I. Basic Violet 16, C.I. Basic Violet 20, C.I. Basic Violet 21, C.I. Basic Violet 39, C.I. Basic Blue 62, C.I. Basic Blue 63, and the like. These can be used singly or in a combination of two or more.

The azo colorants may be any colorant that has azo-N═N— as a chromophore. Examples of such colorants include monoazo colorants, polyazo colorants, metal complex azo colorants, stilbene azo colorants, thiazole azo colorants, and the like. As indicated by color index names, specific examples of such colorants include C.I. Solvent Red 1, C.I. Solvent Red 3, C.I. Solvent Red 23, C.I. Disperse: Red 13, C.I. Disperse Red 52, C.I. Disperse Violet 24, C.I. Disperse Blue 44, C.I. Disperse Red 58, C.I. Disperse Red 88, C.I. Disperse Yellow 23, C.I. Disperse Orange 1, C.I. Disperse Orange 5, C.I. Solvent Red 167:1, and the like. These colorants may be used singly or in a combination of two or more.

The phthalocyanine colorants may be any colorant that has a phthalocyanine structure. Examples of such colorants include blue copper phthalocyanine, greenish blue metal-free phthalocyanine, green highly chlorinated phthalocyanine, yellowish green poorly chlorinated phthalocyanine (brominated chlorinated copper phthalocyanine), and the like.

Specific examples of such colorants include C.I. Pigment Green 7, C.I. Pigment Blue 15, C.I. Pigment Blue 15:3, C.I. Pigment Blue 15:4, C.I. Pigment Blue 15:6, C.I. Pigment Blue 16, C.I. Pigment Green 36, C.I. Direct Blue 86, C.I. Basic Blue 140, C.I. Solvent Blue 70, and the like. These phthalocyanine colorants can be used singly or in a combination of two or more.

In addition to the above general phthalocyanine colorants mentioned above, other phthalocyanine colorants are also usable. Examples of such colorants include compounds that have as central metal(s) at least one metal selected from the group consisting of zinc, iron, cobalt, nickel, lead, tin, manganese, magnesium, silicon, titanium, vanadium, aluminium, iridium, platinum, and ruthenium, with the central metal(s) being coordinated with phthalocyanine; such compounds in which the central metal(s) are bonded to oxygen or chlorine and are coordinated with phthalocyanine; and the like.

The triphenylmethane colorants may be any colorant that has a triphenylmethane structure. Examples of triphenylmethane colorants include C.I. Acid Blue 90, C.I. Acid Green 16, C.I. Acid Violet 49, C.I. Basic Red 9, C.I. Basic Blue 7, C.I. Acid Violet 1, C.I. Direct Blue 41, C.I. Mordnt Blue 1, C.I. Mordnt Violet 1, and the like. These triphenylmethane colorants can be used singly or in a combination of two or more.

The xanthene colorants may be any colorant that has a xanthene structure. Examples of xanthene colorants include C.I. Acid Yellow 74, C.I. Acid Red 52, C.I. Acid Violet 30, C.I. Basic Red 1, C.I. Basic Violet 10, C.I. Mordnt Red 27, C.I. Mordnt Violet 25, and the like. These xanthene colorants can be used singly or in a combination of two or more.

The content of the coloring agent can be appropriately determined according to the kind of coloring agent, the desired hue, etc. The ink composition of the present invention generally preferably contains a coloring agent in an amount of about 0.05 to 5 wt. %, particularly preferably about 0.1 to 1 wt. %.

In the present invention, colorants and pigments other than the coloring agents mentioned above may also be present. In particular, a colorant component that does not change color under plasma treatment atmosphere (“non-color-changing colorant”) may be used. This can more clearly visualize color tone changes from one color to another and can enhance the visual color change recognition effect. The non-color-changing colorant may be a known ink (normal color ink). In this case, the content of the non-color-changing colorant can be appropriately set according to the type of non-color-changing colorant used, etc.

In addition to the coloring agent, the ink composition of the present invention contains at least one of the nonionic surfactants represented by formulae (I) to (V) as a color change accelerator, and further contains a binder resin, a filler, and the like as optional components.

### Nonionic Surfactant

In the ink composition of the present invention, the nonionic surfactant functions as a color change accelerator. Using the nonionic surfactant with a coloring agent can provide more excellent detection sensitivity.

The nonionic surfactant is at least one of the surfactants represented by formulae (I) to (V).

The nonionic surfactants represented by formula (I)

R₁—X-(AO)ₙ-R₂ (I)

(wherein R₁ and R₂ are each independently hydrogen or a straight-chain or branched aliphatic hydrocarbon group having 1 to 30 carbon atoms; X is oxygen or an ester bond; AO is a repeating unit derived from an alkylene oxide; and n is an integer of 1 to 200) are alkylene glycol derivatives.

The nonionic surfactants represented by formula (II)

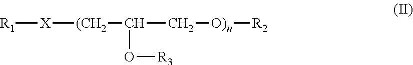

(wherein R₁, R₂, and R₃ are each independently hydrogen or a straight-chain or branched aliphatic hydrocarbon group having 1 to 30 carbon atoms; X is oxygen or an ester bond; and n is an integer of 1 to 200) are polyglycerin derivatives.

In formula (I), examples of AO (monomers) include ethylene oxide, propylene oxide, 1,2-butylene oxide, 2,3-butylene oxide, tetrahydrofuran, styrene oxide, and the like. The form of polymerization of AO may be a homopolymer, or a block copolymer or a random copolymer of two or more kinds of AOs. In formulae (I) and (II), “having 1 to 30 carbon atoms” refers to preferably having 1 to 22 carbon atoms, and more preferably having 10 to 18 carbon atoms. X is preferably oxygen, and n is preferably an integer of 1 to 100.

Specific examples of nonionic surfactants that can be represented by the above formula (I) or (II) include polyethylene glycols (for example, the commercially available product PEG2000 produced by Sanyo Chemical Industries, Ltd.), glycerol, polyethylene glycol-polypropylene glycol copolymers (for example, the commercially available product Epan 710 produced by Dai-Ichi Kogyo Seiyaku Co., Ltd.), and the like.

In the above, polymers wherein at least one of R₁ and R₂ is substituted with a straight-chain or branched aliphatic hydrocarbon group having 1 to 30 carbon atoms are also preferable.

Specific examples include polyoxyethylene (hereinafter “POE”) lauryl ethers (for example, the commercially available product Emulgen 109P), POE cetyl ethers (for example, the commercially available product Emulgen 220), POE oleyl ethers (for example, the commercially available product Emulgen 404), POE stearyl ethers (for example, the commercially available product Emulgen 300, and POE alkyl ether (for example, the commercially available product Emulgen LS-110) (all produced by Kao Corp.); POE tridecyl ethers (for example, the commercially available product Fine Serve TD-150) and polyethylene glycol monostearates (for example, the commercially available product Blaunon S-400A) (both produced by Aoki Oil industrial Co., Ltd.); polyethylene glycol monooleate (for example, the commercially available product Nonion O-4), tetramethylene glycol derivatives (for example, the commercially available product polyserine DC-1100), polybutylene glycol derivatives (for example, the commercially available product Uniol PB-500), and alkylene (glycol derivatives (for example, the commercially available product Unilube 50MB-5) (all produced by NOF Corporation); POE(20) octyldodecyl ether (for example, the commercially available product Emma Rex OD-20) and POE(25) octyldodecyl ether (for example, the commercially available product Emma Rex OD-25) (both produced by Japan Emulsion Co. Ltd.); and the like.

The nonionic surfactants represented by formulae (III) and (IV)

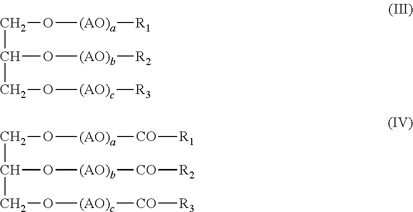

(wherein R₁, R₂, and R₃ are each independently hydrogen or a straight-chain or branched aliphatic hydrocarbon group having 1 to 30 carbon atoms; AO is a repeating unit derived from alkylene oxide; and the sum of a, b, and c is an integer of 3 to 200) are alkylene glycol glyceryl derivatives.

In both of the above formulae, examples of AO (monomer) include ethylene oxide, propylene oxide, 1,2-butylene oxide, 2,3-butylene oxide, tetrahydrofuran, styrene oxide, and the like. The form of polymerization of AO may be a homopolymer, or a block copolymer or a random copolymer of two or more kinds of AO. In both of the above formulae, “having 1 to 30 carbon atoms” refers to preferably having 1 to 22 carbon atoms, and more preferably having 10 to 18 carbon atoms, and the sum of a, b, and c is preferably an integer of 3 to 50.

Examples of nonionic surfactants represented by formula (III) include compounds wherein R₁ is an isostearic acid residue, R₂ and R₃ are hydrogen, and AO (monomer) is ethylene oxide. Specific examples include POE glyceryl isostearates (for example, the commercially available product Uniox GM-30IS produced by NOF Corporation).

Examples of nonionic surfactants represented by formula (IV) include compounds wherein R₁ to R₃ are isostearic acid residues, and AO (monomer) is ethylene oxide. Specific examples include POE glyceryl triisostearate (for example, the commercially available product Uniox GT-30IS produced by NOF Corporation).

The nonionic surfactants represented by formula (V)

R₁—X-(AO)ₚ-R₂—C≡C—R₃═X-(AO)_{q}-R₄ (V)

(wherein R₁, R₂, R₃, and R₄ are independently hydrogen or a straight-chain or branched aliphatic hydrocarbon group having 1 to 30 carbon atoms, X is oxygen or an ester bond, AO is a repeating unit derived from alkylene oxide, and the sum of p and q is an integer of 0 to 20) are acetylene glycol derivatives.

In formula (V), examples of AO (monomers) include ethylene oxide, propylene oxide, 1,2-butylene oxide, 2,3-butylene oxide, tetrahydrofuran, styrene oxide, and the like. The polymerization form of AO includes a homopolymer, or a block copolymer or a random copolymer of two or more kinds of AOs. In formulae (I) and (II), “having 1 to 30 carbon atoms” refers to preferably having 1 to 22 carbon atoms, X is preferably oxygen, and the sum of p and q is preferably an integer of 0 to 10.

Examples of nonionic surfactants represented by formula (V) include compounds wherein R₁ and R₄ are hydrogen, R₂ and R₃ are >C(CH₃) (i-C₄H₉), X is oxygen, and p+q=0. Specific examples include 2,4,7,9-tetramethyl-5-decyn-4,7-diol (for example, the commercially available product Surfynol 104H produced by Air Products Japan, Inc.).

The nonionic surfactants represented by formulae (I) to (V) can be used singly or in a combination of two or more.

The content of the nonionic surfactant can be suitably determined according to the types of nonionic surfactant and coloring agent used, etc. In consideration of the preservability in the composition and color-change-accelerating effect, the content of the nonionic surfactant in the ink composition is generally preferably about 0.2 to 10 wt. %, and particularly preferably 0.5 to 5 wt. %.

### Binder Resin

The resin binder may be suitably selected according to the type of base material, etc. Known resin components used in ink compositions for writing, printing, etc., can be used. Examples of resin binders include maleic resins, ketone resins, polyvinyl butyral resins, cellulose resins, acrylic resins, styrene maleic resins, styrene acrylic acid resins, polyester resins, polyamide resins, polyacrylonitrile resins, polyimide resins, polyvinyl pyrrolidone resins, polyacrylamide resins, polyvinyl imidazole resins, polyethylene imine resins, amino resins, and the like.

Cellulose resins are particularly preferable for use in the present invention. The use of a cellulose resin can impart excellent fixing properties even when the ink composition contains an extender (e.g., silica), and can efficiently prevent falling and detachment from the base material. Efficiently producing cracks on the surface of the coating film of the ink composition can help enhance the sensitivity of the indicator.

In the present invention, the binder resins may be all or partially nitrogen-containing polymers other than the resins mentioned above. The nitrogen-containing polymers function as sensitivity enhancers as well as binders. Specifically, the use of such a sensitivity enhancer can enhance the accuracy (sensitivity) of plasma treatment detection. This ensures color change even in a package for detecting plasma treatment; therefore, it is very advantageous for use as an indicator in the package.

Examples of nitrogen-containing polymers include synthetic resins, such as polyamide resins, polyimide resins, polyacrylonitrile resins, amino resins, polyacrylamides, polyvinylpyrrolidones, polyvinylimidazoles, and polyethyleneimines. These resins can be used singly or in a combination of two or more. In particular, polyamide resins are preferably used in the present invention.

The type, molecular weight, etc., of polyamide resin are not particularly limited. Known or commercially available polyamide resins can be used. Among these, a polyamide resin that is a reaction product of a dimer of linoleic acid with a diamine or polyamine (a long-chain linear polymer) is suitable for use. Polyamide resins are thermoplastic resins that have a molecular weight of 4,000 to 7,000. Commercially available products can be used as such resins.

In the present invention, using phenolic resin(s) other than the resins mentioned above as at least one or all of the binder resins can enhance heat resistance of the ink composition and a color-changing layer formed using the ink composition.

The phenolic resin may be any colorant that has a phenol structure. For example, at least one member selected from the group consisting of alkylphenol resins, terpene phenolic resins, and rosin-modified phenolic rears can be suitably used. Such phenolic resins can be used singly or in a combination of two or more.

The content of the binder resin can be appropriately determined according to the types of binder resin and coloring agent used, etc. The amount of the binder in the ink composition is generally preferably about 50 wt. % or less, and particularly preferably 5 to 35 wt. %. When the nitrogen-containing polymer is used as a binder resin, the amount of the nitrogen-containing polymer in the ink composition is preferably about 0.1 to 50 wt. %, and particularly preferably 1 to 20 wt. %.

### Extender

Any extender can be used, and examples of extenders include bentonite, activated clay, aluminum oxide, silica, silica gel, and like inorganic materials. Materials known as extender pigments can also be used. Among these, at least one member selected from the group consisting of silica, silica gel, and alumina is preferable, and silica is particularly preferable. When silica or the like is used, cracks can be effectively produced particularly on the surface of the color-changing layer. As a result, the detection sensitivity of the indicator can be further increased.

The content of the extender can be suitably determined according to the types of extender and coloring agent used, etc. The content of the extender in the ink composition is generally preferably about 1 to 30 wt. %, and particularly preferably 2 to 20 wt. %.

### Other Additives

If required, the ink composition of the present invention may appropriately contain components used in known inks, such as solvents, leveling agents, antifoaming agents, UV absorbers, and surface conditioners.

Solvents that can be used in the present invention may be any solvent that is used in ink compositions for printing, writing, etc. Usable solvents are various solvents such as alcohol-based, polyhydric alcohol-based, ester-based, ether-based, ketone-based, hydrocarbon-based, and glycol ether-based solvents. The solvent to be used can be suitably selected in consideration of the solubility of the colorant and binder resin used, etc. It is necessary to use a solvent that can be removed from a coating film at ordinary temperature or by heating and drying. The solvent is distinguished from the nonionic surfactant in this point. As solvents, for example, rapid drying solvents that have a relative evaporation rate of 1.0 or more, with the evaporation rate of n-butyl acetate being defined as 1.0, are suitable for gravure printing. Solvents with a drying rate adjusted by appropriately mixing solvents having a relative evaporation rate of 0.01 to 1.0 are suitable for screen printing.

The content of the solvent can be suitably determined according to the types of solvent and coloring agent used, etc. In general, the content of the solvent in the ink composition is preferably about 40 to 95 wt. %, and particularly preferably 60 to 90 wt. %.

The viscosity can be adjusted by adjusting the content of the solvent, thus providing an ink composition having a viscosity suitable for various printing methods. In the present invention, the ink composition preferably has a viscosity of less than 12,000 mPa·s. The viscosity particularly suitable for silk screen printing is about 500 to 8,000 mPa·s. The viscosity suitable for gravure printing is about 10 to 500 mPa·s.

The components of the ink composition of the present invention can be added all at once or sequentially, and mixed uniformly by using a known stirrer, such as a homogenizer or a dissolver. For example, first the coloring agent mentioned above and at least one member selected from the group consisting of binder resins, cationic surfactants, and extenders (other additives as required) may be sequentially added to a solvent, and the resultant mixture may be mixed and stirred using a stirrer.

### 2. Indicator for Detecting Plasma Treatment

The indicator of the present invention comprises a color-changing layer comprising the ink composition of the present invention. The color-changing layer can typically be formed by applying or printing the ink composition of the present invention on a base material. Any base material can be used as the base material insofar as the color-changing layer can be formed on it.

Examples of base materials include metals or alloys, ceramics, glass, concrete, plastics (polyethylene terephthalate (PET), polypropylene, nylon, polystyrene, polysulfone, polycarbonate, polyimide, etc.), fibers (non-woven fabric, woven fabric, other fibrous sheets), and composite materials thereof. Synthetic resin fiber paper (synthetic paper), such as polypropylene synthetic paper or polyethylene synthetic paper, can also be suitably used.

The color-changing layer of the present invention includes layers that change color to other colors and also includes layers that fade in color or become decolorized.

The color-changing layer can be formed using the ink composition of the present invention according to known printing methods, such as silk screen printing, gravure printing, offset printing, relief printing, and flexographic printing. The color-changing layer can also be formed by various methods other than printing methods. For example, the color-changing layer can be formed by immersing a base material into an ink composition. Such methods are particularly preferable for materials into which ink permeates, such as nonwoven fabrics.

The color-changing layer preferably has cracks on the surface. Specifically, the color-changing layer preferably has open pores formed on the surface of the color-changing layer and is porous. With this structure, the detection sensitivity of the plasma treatment indicator can be further enhanced. In this case, the desired color change effect can be obtained even when the color-changing layer is disposed in the plasma treatment detection package. Cracks can be effectively formed by using a cellulose resin as a binder for the ink composition of the present invention. Specifically, use of a cellulose resin enables the formation of cracks as mentioned above, while maintaining good fixing properties.

In the present invention, a non-color-changing layer whose color does not change in a plasma treatment atmosphere may be further formed on the base material and/or on the color-changing layer. The non-color-changing layer can typically be formed by using a commercially available normal color ink. For example, water-based inks, oil-based inks, solventless inks, and the like can be used. The ink for use in the formation of the non-color-changing layer may optionally contain components used in known inks, such as resin binders, extenders, and solvents.

The non-color-changing layer may be formed in the same manner as the formation of the color-changing layer. For example, the non-color-changing layer can be formed by using a normal color ink according to a known printing method, such as silk screen printing, gravure printing, offset printing, relief printing, or flexographic printing. The order of printing the color-changing layer and the non-color-changing layer is not particularly limited, and may be suitably selected according to the design to be printed, etc.

The indicator of the present invention may comprise one color-changing layer and one non-color-changing layer, or two or more color-changing layers and two or more non-color-changing layers. Color-changing layers may be laminated together or non-color-changing layers may be laminated together. In this case, compositions of the color-changing layers may be the same or different. Compositions of the non-color-changing layers may also be the same or different.

Further, the color-changing layer and the non-color-changing layer may be formed partially or entirely on the base material or on the layers. In these cases, in particular, in order for the color-changing layer to reliably change color, it is sufficient that color-changing layer(s) and non-color-changing layer(s) be formed in such a manner that at least one color-changing layer is partially or entirely exposed to a plasma treatment atmosphere.

In the present invention, the color-changing layer and non-color-changing layer may be freely combined insofar as completion of the plasma treatment can be confirmed. For example, the color-changing layer and non-color-changing layer can be formed in such a manner that the color difference between them can be recognized only after the color of the color-changing layer changes, or in such a manner that the color difference between them disappears only after the color of the color-changing layer changes. In the present invention, it is particularly preferable to form the color-changing layer and non-color-changing layer in such a manner that the color difference between them can be recognized only after the color of the color-changing layer changes.

To enable the color difference to be recognized, for example, the color-changing layer and non-color-changing layer may be formed in such a manner that at least one of characters, patterns, and symbols appear only after the color of the color-changing layer changes. In the present invention, characters, patterns, and symbols include any information that notifies color change. Such characters and the like may be suitably designed according to the intended use, etc.

The color of the non-color-changing layer and the color of the color-changing layer before color change may be different from each other. For example, the color-changing layer and the non-color-changing layer may have substantially the same color, and the color difference (contrast) between the color-changing layer and the non-color-changing layer may be made recognizable only after color change occurs.

According to the indicator of the present invention, the color-changing layer and the non-color-changing layer can be formed in such a manner that the color-changing layer and the non-color-changing layer do not overlap. This can save the amount of ink used.

In the present invention, another color-changing layer or non-color-changing layer may be further formed on either the color-changing layer or the non-color-changing layer, or on both. For example, when a color-changing layer having a different design is formed on a layer comprising a color-changing layer and a non-color-changing layer formed in such a manner that the color-changing layer and the non-color-changing layer are not overlapped (referred to as “a color changing/non-color-changing layer”), the boundary between the color-changing layer and the non-color-changing layer in the color changing/non-color-changing layer cannot be substantially recognized. Thus, better design can be attained.

The indicator of the present invention is applicable to any plasma treatment using a gas for generating plasma. Thus, the indicator can be used for both reduced-pressure plasma treatment and atmospheric-pressure plasma treatment.

Reduced-pressure plasma treatments may be used, for example, in cleaning, surface modification, etc., of flat panel displays (e.g., liquid crystal displays); film production, ashing, cleaning, surface modification, etc., in semiconductor manufacturing processes; cleaning, surface modification, etc., of mounting substrates or printed-circuit substrates; sterilization, etc., of medical instruments; and cleaning, surface modification, etc., of mounted components.

Atmospheric-pressure plasma treatments can be used, for example, in film production, ashing, cleaning, surface modification, etc., of flat panel displays (e.g., liquid crystal displays); cleaning, surface modification, etc., of mounting substrates or printed-circuit substrates; surface modification of automobiles, aircraft components, etc.; disinfection, sterilization, medical treatment, etc., in the medical field (dentistry or surgery); and the like.

The gas for generating reduced-pressure plasma may be any gas that can generate plasma by applying AC voltage, pulse voltage, high-frequency waves, microwaves, etc., under reduced pressure. Examples of such gases include oxygen, nitrogen, hydrogen, chlorine, hydrogen peroxide, helium, argon, silane, ammonia, sulfur bromide, water vapor, nitrous oxide, tetraethoxysilane, carbon tetrafluoride, trifluoromethane, carbon tetrachloride, silicon tetrachloride, sulfur hexafluoride, titanium tetrachloride, dichlorosilane, trimethylgallium, trimethylindium, trimethylaluminum, and the like. These gases for generating reduced-pressure plasma can be used singly or in a combination of two or more.

The gas for generating atmospheric pressure plasma may be any gas that can generate plasma by applying AC voltage, pulse voltage, high-frequency waves, microwaves, etc. at atmospheric pressure. Examples of such gases include oxygen, nitrogen, hydrogen, argon, helium, air, and the like. These gases for generating atmospheric-pressure plasma can be used singly or in a combination of two or more.

When the indicator of the present invention is used, for example, the indicator of the present invention may be placed in a plasma treatment device using a gas for generating plasma (specifically a device for plasma treatment that generates plasma by application of AC voltage, pulse voltage, high-frequency waves, microwaves, etc., in an atmosphere containing a gas for generating plasma to perform plasma treatment) or disposed on or near the item(s) to be treated that are accommodated in the device, and may be exposed to a plasma treatment atmosphere. In this case, a predetermined plasma treatment can be detected from color change of the indicator placed in the device.

The indicator of the present invention can be used in the form of an indicator card as is. If the color-changing layer is in the form of a known bar code and the bar code has its conditions set so that it can be read by a bar code reader at the stage where a specific plasma treatment (degree of color change) has been completed, completion of plasma treatment and subsequent plasma-treated item distribution management can be centrally managed with bar codes. The present invention also includes inventions directed to an indicator, a method for plasma treatment management, and a method for distribution management used for this purpose.

### 3. Package

The present invention includes a package for plasma treatment comprising a gas permeable package and the indicator of the present invention disposed on the inner surface of the package.

The gas permeable package is preferably a package that can be subjected to a plasma treatment with the item(s) to be treated being contained in the package. Known or commercially available packages that are used as packages (pouches) for plasma treatment can be used. For example, a package formed of polyethylene fiber (polyethylene synthetic paper) can be suitably used. After the item(s) to be treated are placed in this package and the opening is sealed by heat sealing or the like, the whole package can be treated in the plasma treatment device.

As long as the indicator of the present invention is disposed on the inner surface of the package, the method for disposing the indicator is not particularly limited. In addition to methods using adhesives, heat sealing, etc., the indicator can also be formed by directly applying or printing the ink composition of the present invention onto the inner surface of the package. When an indicator is formed by such application or printing, the indicator can also be formed at the stage of manufacturing the package.

The package of the present invention preferably has a transparent window in a part of the package so as to allow the indicator to be visually checked from the outside. For example, the package may be formed using a transparent sheet and the polyethylene synthetic paper mentioned above, and the indicator may be disposed on the inner surface of the package at such a position as to allow the indicator to be visually checked through the transparent sheet.

When plasma treatment is performed using the package of the present invention, a method including the following steps may be used: a step of placing item(s) to be treated into the package, a step of sealing the package containing the item(s) to be treated, and a step of disposing the package in a plasma treatment atmosphere. More specifically, after the item(s) to be treated are placed in the package, the package is sealed according to a known method, such as heat sealing. Subsequently, the whole package is disposed in a plasma treatment atmosphere. For example, the package is disposed in a treatment chamber of a known or commercially available plasma treatment device and subjected to the treatment. After the treatment has been completed, the whole package is removed from the treatment chamber, and the treated item(s) can be kept in the package as is until being put to use. In this plasma treatment, the package is preferably kept in a plasma treatment atmosphere until the color of the color-changing layer of the indicator has changed.

### 4. Image-Drawing Tool

The present invention further includes an invention directed to an image-drawing tool comprising the ink composition of the invention.

The term “image-drawing tool” as used herein is meant to include writing instruments (e.g., markers, ballpoint pens, containers with brushes, and stamps) and application instruments. When there is no space for disposing the indicator around the item(s) to be treated with plasma due to the size of the plasma treatment device, a part of the item(s) to be treated with plasma is marked with the image-drawing tool, and completion of a specific plasma treatment can be confirmed by color change of the mark.

Among the writing instruments, for example, those in the form of marker pens configured to allow the ink composition to seep out through the pen nib, writing instruments with an inner core such as felt pens, or ballpoint pens are preferable. The ballpoint, pen is a writing instrument that includes an ink-containing tube filled with an ink composition and accommodated within a tubular holder, and a pen tip at which a small ball is disposed in such a manner that the ink composition seeps out through the pen nib upon writing. The inner-core writing instrument is a writing instrument comprising, as an ink-containing member, an inner core formed by binding fibers into a bundle, and a pen nib (tip) through which the ink contained in the inner core seeps out, the pen nib member being, for example, a ball, fibers, a plastic tip, a brush-like member, or an ink-brush-like member.

Writing instruments can be assembled by using known members. For example, a ballpoint pen can be manufactured by placing the ink composition of the present invention into an ink-containing tube that is formed of a known material and has a known size and then assembling the ink-containing tube with a ballpoint pen tip that is formed of a known material and has a known structure, according to a known assembling method. The ink-containing tube is, for example, a pipe made of a synthetic resin, such as polyethylene or polypropylene, or a metal pipe. The ballpoint pen tip may be one commonly used, and a ballpoint pen tip that has a difference of, for example, 0.01 mm or more between the diameter of the ball and the inner diameter of the ball housing can be used.

When such an image-drawing tool is produced, the viscosity of the ink composition of the present invention can be adjusted according to the properties and ease of handling of the image-drawing tool.

### ADVANTAGEOUS EFFECTS OF INVENTION

The ink composition of the present invention contains a colorant and a nonionic surfactant, wherein (1) the colorant is at least one member selected from the group consisting of anthraquinone colorants, methine colorants, azo colorants, and phthalocyanine colorants, and (2) the nonionic surfactant is at least one nonionic surfactant represented by formulae (I) to (V). Based on this feature, the indicator for detecting plasma treatment comprising a color-changing layer formed using this ink composition can individually detect the completion of plasma treatment of the items to be treated by using a gas for generating plasma without using a large device.

### BRIEF DESCRIPTION OF DRAWINGS

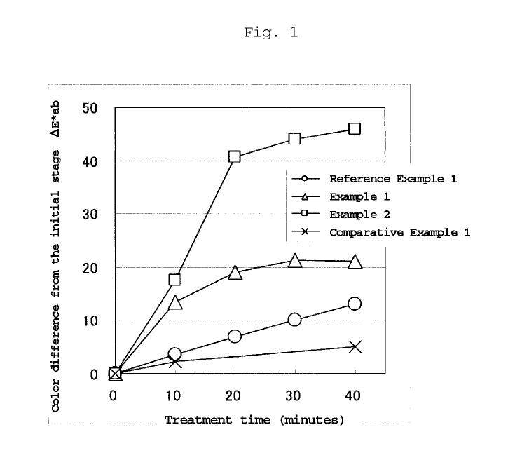

FIG. 1 shows the relationship between the treatment time and color change (color difference) (ΔE*ab) in Examples 1 and 2, Reference Example 1, and Comparative Example 1, when nitrogen plasma treatment is performed for different periods of time: 10, 20, 30, and 40 minutes.

### DESCRIPTION OF EMBODIMENTS

The present invention is described below in more detail with reference to Examples and Comparative Examples. However, the present invention is not limited to the embodiments described in the examples.

### EXAMPLES 1 TO 13, COMPARATIVE EXAMPLES 1 TO 2, AND REFERENCE EXAMPLES 1 to 2

Ink compositions were prepared by mixing the components according to the formulations shown in Table 1.

The ink compositions were screen-printed on white Toyobo crisper K2323 PET film and dried to obtain purple indicators.

### TEST EXAMPLE 1

Each indicator was subjected to a heat resistance test and to a color change test. The test methods and evaluation criteria are as follows.

### Heat Resistance Test

First, the chromaticity L*a*b* of the color-changing layer of each indicator (before heat treatment) was measured with a handheld colorimeter NP-11A produced by Nippon Denshoku Industries Co., Ltd.

Next, each indicator was heat-treated by being allowed to stand at 170° C. for 10 minutes. These conditions were intended to simulate the situation in which unintended overheating occurs because gas for generating plasma is not appropriately supplied in a plasma treatment device due to certain defects.

After each indicator was allowed to stand for 10 minutes, the indicator was removed from the device and chromaticity L*a*b* of the color-changing layer (after heat treatment) was measured in the same manner as above.

The chromaticity before the heat treatment was defined as L*₁, a*₁, and b*₁, whereas the chromaticity after the heat treatment was defined as L*₂, a*₂, and b*₂. The difference in chromaticity (color difference) between the two was indicated by ΔE*ab and calculated using the following formula.

Color difference ΔE*ab=[(L*₂−L*₁)²+(a*₂−a*₁)²+(b*₂−b*₁)²]^{1/2}

Table 1 shows the test results.

### Color Change Tests

### Nitrogen Plasma Treatment

Indicators were set in a TMP-0063A microwave plasma treatment device produced by Toshiba Corporation. Nitrogen was prepared as a gas for generating plasma. A nitrogen plasma treatment was performed by applying microwaves at a frequency of 2.45 GHz and at an output of 1 kW for 10 minutes with a nitrogen flow of 0.5 L/min and a degree of vacuum of 1.7 Torr.

The color change (color difference) between before and after the plasma treatment was measured using a handheld CR-300 colorimeter produced by Konica Minolta, Inc. Table 1 shows color difference measurement results.

### Oxygen Plasma Treatment

Each indicator was set to a TMP-0063A microwave plasma treatment device produced by Toshiba Corporation. Oxygen was prepared as a gas for generating plasma. Oxygen plasma treatment was performed by applying microwaves at a frequency of 2.45 GHz at an output of 0.5 kW for 3 minutes with an oxygen flow of 0.5 L/min and a degree of vacuum of 1.7 Torr.

The color change difference between before and after the plasma treatment was measured using a handheld CR-300 colorimeter produced by Konica Minolta, Inc. Table 1 shows color difference measurement results.

### Discussion

All of the indicators changed color to green due to the nitrogen plasma treatment and changed color to pink due to oxygen plasma. Reference Examples 1 and 2 show the results obtained by using a Nikkol CA2580 cationic surfactant, which is used as a conventional color change accelerator in ink compositions for detecting plasma treatment. The results show that compared to Comparative Examples 1 and 2, which do not contain any color change accelerators, Reference Examples 1 and 2 have color-change-accelerating effects.

Examples 1, 2 and 4 to 7 exhibited a color change difference that is equivalent to or greater than that of Reference Example 1, whereas Examples 8 and 10 to 13 exhibited a color change difference that is greater than that of Reference Example 2. Thus, color-change-accelerating effects were observed. These are examples in which addition of a nonionic surfactant imparts color-change-accelerating effects to both nitrogen plasma and oxygen plasma.

In contrast, the color changes (color differences) in Example 3 and Example 9 were greater than those in Reference Example 1 (in comparison with Example 3) and Reference Example 2 (in comparison with Example 9) only in regard to nitrogen plasma. The color-change-accelerating effect was not observed in regard to oxygen plasma. That is, Examples 3 and 9 are examples in which addition of a nonionic surfactant selectively imparts color-change-accelerating effects to nitrogen plasma.

FIG. 1 shows the relationship between the treatment time and color change (color difference) (ΔE*ab) in Examples 1 and 2, Reference Example 1, and Comparative Example 1 when the nitrogen plasma treatment was performed for different periods of time: 10, 20, 30, and 40 minutes.

The results in FIG. 1 show that color change gradually progresses in all of the Examples, and that compared to Comparative Example 1, color change progresses in a shorter time in the ascending order of Reference Example 1, Example 1, and Example 2. That is, the indicators for detecting plasma treatment using the ink compositions of the present invention have higher detection sensitivity than conventional indicators.

It is also found that the color-changing layers of the indicators obtained in Examples 1 to 7, 9, 10, and 13 and Comparative Example 1, which comprises a phenolic resin as the binder resin or one of the binder resins, have a smaller color change difference (ΔE*ab) in the heat-resistance test, compared to the color-changing layers of the indicators obtained in References 1 and 2, Comparative Example 2, and Examples 11 and 12, which do not contain any phenolic resins as binder resins. These results show that using a phenolic resin as a binder resin enhances heat resistance of the color-changing layer. Accordingly, when the composition contains a phenolic resin as a binder resin, color change due to heat alone can be inhibited even when a gas for generating plasma is not appropriately supplied in a plasma treatment device due to certain defects and unintended overheating occurs.

### TEST EXAMPLE 2

### Color Change Tests

The color-changing layer of the indicator in Example 1, which was prepared using the ink composition of Example 1, (before plasma treatment) was subjected to various plasma treatments described below.

The color change (color difference) ΔE*ab between before and after plasma treatment was measured using is handheld CR-300 colorimeter produced by Konica Minolta.

In each of the plasma treatments, the color change (color difference) ΔE*ab between before and after the treatment was confirmed to be 5 or more. Specifically, the results demonstrate that the completion of the plasma treatments can be confirmed.

### Plasma Treatment Conditions

### Plasma-Treatment (1): Water Vapor/Hydrogen Peroxide Plasma

Device: BP-1 High-frequency plasma treatment device (produced by Samco, Inc.)
Steam: 2 mmol/min, electric power: 75 W, pressure: 40 Pa, distance between electrodes: 50 mm, treatment time: 20 min

### Plasma Treatment (2): Carbon Tetrafluoride Plasma

Device: BP-1 high-frequency plasma treatment device (produced by Samco Inc.)
CF₄ gas: 5 ml/min, electric power: 75 H, pressure: 100 Pa, distance between electrodes: 50 mm, treatment time: 10 min

### Plasma Treatment (3): Argon Plasma

Device: BP-1 high-frequency plasma treatment device (produced by Samco, Inc.)
Ar gas: 20 ml/min, electric power: 75 W, pressure: 20 Pa, distance between electrodes: 50 mm, treatment time: 30 min

### Plasma Treatment (4): Atmospheric-Pressure Plasma

Device: Plasma-treatment system (produced by Rikaseiki Co., Ltd.)
Gas: Dry air: 40 L/h, irradiation distance: 10 mm, treatment time: 400 m/s×10 times

### Plasma Treatment (5): Atmospheric-Pressure Plasma

Device: Tough plasma (produced by Fuji Machine Mfg. Co., Ltd.)
Gas: N₂: 29.7 L/min+dry air: 0.3 L/min, irradiation distance: 10 mm, treatment time: 20 m/s×10 times

### Plasma Treatment (6): Atmospheric-Pressure Plasma

Device: Precise 300C (produced by e-Square Co., Ltd.)
Gas: N₂: 125/min+H₂O: 2 L/min, irradiation distance: 1 mm, treatment time: 1 m/s×10 time

### Plasma Treatment (7): Atmospheric-Pressure Plasma

Device: Precise 300C (produced by e-Square Co., Ltd.)
Gas: N₂: 125/min+H₂: 3.6 L/min, irradiation distance: 1 mm, processing time: 1 m/s×10 times

### TEST EXAMPLE 3

The color-changing layer of the indicator in Example 2, which was prepared using the ink composition of Example 2, was subjected to the same color change tests as in Test Example 2. Under all of plasma treatment conditions (1) to (7), the color change (color difference) ΔE*ab between before and after the treatment was found to be 5 or more. That is, the results demonstrate that completion of the plasma treatment can be confirmed.

### TEST EXAMPLE 4

The color-changing layer of the indicator obtained in Example 3, which was prepared using the ink composition of Example 3, was subjected to the same color change test as in Test Example 2. Under all of plasma treatment conditions (1) to (7), the color change (color difference) ΔE*ab between before and after the treatment was confirmed to be 5 or more. More specifically, the results demonstrate that completion of the plasma treatment can be confirmed.

### TEST EXAMPLE 5

The color-changing layer of the indicator in Example 4, which was prepared using the ink composition of Example 4, was subjected to the same color change tests as in Test Example 2. Under all of the plasma treatment conditions (1) to (7), the color change (color difference) ΔE*ab between before and after the treatment was confirmed to be 5 or more. More specifically, the results demonstrate that completion of the plasma treatments can be confirmed.

### EXAMPLES 14 to 17

One part by weight of propylene glycol monomethyl ether was added per part by weight of each of the ink compositions obtained in Examples 1 to 4. Each mixture was stirred with a stirrer for 15 minutes to prepare an oil-based ink composition for ballpoint pens. A pen body comprising a super-hard ball with a diameter of 0.7 mm and a ballpoint pen socket made of nickel silver was pressed into an end of a polypropylene tube. After the oil-based ink compositions for ballpoint pens were placed inside, bubbles in the ink were removed by centrifugation to prepare free-ink ballpoint pens.

White Toyobo crisper K2323 PET film on which images were drawn with the ballpoint pens was subjected to the nitrogen plasma treatment and the oxygen plasma treatment. The results confirm that the drawn images changed color as in Examples 1 to 4 in which screen printing was performed).

### EXAMPLES 18 to 20

Two parts by weight of propylene glycol monomethyl ether was added per part by weight of each of the ink compositions obtained in Examples 5 to 7. Each mixture was stirred with a stirrer for 15 minutes to prepare an ink composition for marking pens. A writing instrument with a felt pen nib (trade name: Pen-Touch, permanent marker pen produced by Sakura Color Products Corp.) was filled with each of the oil-based ink compositions for marking pens.

White Toyobo Crisper K2323 PET film on which images were drawn with the marking pens was subjected to the nitrogen plasma treatment and the oxygen plasma treatment. The results confirm that the drawn images changed color as in Examples 5 to 7 (in which screen printing was performed).

### EXAMPLES 21 to 27

Two parts by weight of propylene glycol monomethyl ether was added per part by weight of each of the ink compositions obtained in Examples 8 to 13. Each mixture was stirred with a stirrer for 15 minutes to prepare an oil-based ink composition for marking pens. Inner-core marking pens were filled with the oil-based ink compositions for marking pens.

White Toyobo Crisper K2323 PET film on which images were drawn with the marking pens was subjected to the nitrogen plasma treatment and the oxygen plasma treatment. The results confirm that the drawn images changed color as in Examples 5 to 7 in which screen printing was performed).

TABLE 1

| | Reference | | | | | | | | Comparative | Reference | | | | | | | Comparative |
|---|---|---|---|---|---|---|---|---|---|---|---|---|---|---|---|---|---|
| | Example | Example | | | | | | | Example | Example | Example | | | | | | Example |
| Composition | 1 | 1 | 2 | 3 | 4 | 5 | 6 | 7 | 1 | 2 | 8 | 9 | 10 | 11 | 12 | 13 | 2 |
| C.I. Solvent Red 167:1 (azo colorant) | 0.3 | 0.3 | 0.3 | 0.3 | 0.3 | 0.3 | 0.3 | 0.3 | 0.3 | 0.3 | 0.3 | 0.3 | 0.3 | 0.3 | 0.3 | 0.3 | 0.3 |
| C.I. Pigment Green 7 (phthalocyanine colorant) | 0.9 | 0.9 | 0.9 | 0.9 | 0.9 | 0.9 | 0.9 | 0.9 | 0.9 | 0.9 | 0.9 | 0.9 | 0.9 | 0.9 | 0.9 | 0.9 | 0.9 |
| Versamid JP802 (polyamide produced by BASF) | 7.1 | 7.1 | 7.1 | 7.1 | 7.1 | 7.1 | 7.1 | 7.1 | 7.1 | 10.7 | 7.1 | 7.1 | | 10.0 | | | 10.7 |
| Shola-men RS7 (nitrocellulose produced by SNPE Japan K.K.) | 3.6 | 3.6 | 3.6 | 3.6 | 3.6 | 3.6 | 3.6 | 3.6 | 3.6 | | 3.6 | | 7.0 | | 10.6 | | |
| YS Polystar U115 (terpenephenol produced by Yasuham | | 2.0 | 2.0 | 2.0 | 2.0 | 2.0 | 2.0 | 2.0 | 2.0 | | | 2.0 | 2.0 | | | 9.0 | |
| Chemical Co., Ltd.) | | | | | | | | | | | | | | | | | |
| Cyclohexanone | 13.9 | 13.9 | 13.9 | 13.9 | 13.9 | 13.9 | 13.9 | 13.9 | 13.9 | 13.9 | 13.9 | 13.9 | 13.9 | 13.9 | 13.9 | 13.9 | 13.9 |
| Butyl cellulosolve | 57.0 | 55.0 | 55.0 | 55.0 | 55.0 | 55.0 | 55.0 | 55.0 | 57.9 | 57.0 | 57.0 | 58.6 | 58.7 | 57.7 | 57.2 | 58.8 | 59.9 |
| Aerosil R-972 (silica produced by Nippon | 14.3 | 14.3 | 14.3 | 14.3 | 14.3 | 14.3 | 14.3 | 14.3 | 14.3 | 14.3 | 14.3 | 14.3 | 14.3 | 14.3 | 14.3 | 14.3 | 14.3 |
| Aerosil Co., Ltd.) | | | | | | | | | | | | | | | | | |
| Nikkol CA2580 (a quaternary ammonium | 2.9 | | | | | | | | | 2.9 | | | | | | | |
| salt surfactant produced by Nippon | | | | | | | | | | | | | | | | | |
| Chemicals) | | | | | | | | | | | | | | | | | |
| PEG2000 (polyethylene glycol produced by | | 2.9 | | | | | | | | | 2.9 | | | | | | |
| Sanyo Chemical Industries. Ltd.) | | | | | | | | | | | | | | | | | |
| Unilob 50MB-5 (analkylene glycol | | | 2.9 | | | | | | | | | | | 2.9 | | | |
| derivative produced by NOF Corporation) | | | | | | | | | | | | | | | | | |
| Emulgen 109P (a polyoxy alkylether | | | | 2.9 | | | | | | | | 2.9 | | | | | |
| produced by Kao Corporation) | | | | | | | | | | | | | | | | | |
| Emulgen LS-110 (a polyoxy alkylether | | | | | 2.9 | | | | | | | | 2.9 | | | | |
| produced by Kao Corporation) | | | | | | | | | | | | | | | | | |
| Polyserine DC-1100 (a tertramethylene glycol | | | | | | 2.9 | | | | | | | | | 2.9 | | |
| derivative produced by NOF Corporation) | | | | | | | | | | | | | | | | | |
| Uniol PR-500 (a polybutylene glycol | | | | | | | 2.9 | | | | | | | | | | |
| derivative produced by NOF Corporation) | | | | | | | | | | | | | | | | | |
| Surfynol 104H (acetylenediol produced by | | | | | | | | 2.9 | | | | | | | | 2.9 | |
| Air Products Japan, Inc.) | | | | | | | | | | | | | | | | | |
| Total | 100.0 | 100.0 | 100.0 | 100.0 | 100.0 | 100.0 | 100.0 | 100.0 | 100.0 | 100.0 | 100.0 | 100.0 | 100.0 | 100.0 | 100.0 | 100.0 | 100.0 |
| Color change difference ΔE*ab in the heat | 13.0 | 4.0 | 3.0 | 3.0 | 3.0 | 2.0 | 4.0 | 2.0 | 2.0 | 18.0 | 22.0 | 2.0 | 3.0 | 19.0 | 16.0 | 1.0 | 11.0 |
| resistance test | | | | | | | | | | | | | | | | | |
| Color change difference ΔE*ab after | 3.5 | 13.5 | 17.6 | 10.8 | 15.1 | 17.0 | 17.8 | 5.0 | 3.4 | 6.6 | 11.2 | 17.1 | 9.1 | 19.0 | 14.3 | 9.9 | 4.1 |
| nitrogen plasma treatment | | | | | | | | | | | | | | | | | |
| Color change difference ΔE*ab after oxygen | 4.4 | 4.6 | 7.2 | 0.5 | 5.5 | 11.4 | 4.8 | 5.1 | 2.1 | 6.8 | 10.1 | 3.5 | 7.1 | 14.0 | 8.8 | 8.1 | 2.8 |
| plasma treatment | | | | | | | | | | | | | | | | | |

1. An ink composition for detecting plasma treatment, the composition comprising a colorant and a nonionic surfactant,
(1) the colorant being at least one member selected from the group consisting of anthraquinone colorants, methine colorants, azo colorants, phthalocyanine colorants, triphenylmethane colorants, and xanthene colorants; and
(2) the nonionic surfactant being at least one of the surfactants represented by formulae (I) to (V): 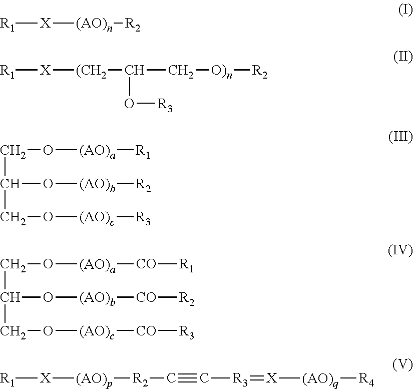
wherein R₁, R₂, R₃, and R₄ are each independently hydrogen or a straight-chain or branched aliphatic hydrocarbon group having 1 to 30 carbon atoms; X is oxygen or an ester bond; AO is a repeating unit derived from an alkylene oxide; n is an integer of 1 to 200; the sum of a, b and c is an integer of 3 to 200; and the sum of p and q is an integer of 0 to 20.

2. The ink composition according to claim 1, further comprising at least one member selected from the group consisting of binder resins and fillers.

3. The ink composition according to claim 2, wherein the binder resins are all or partially nitrogen-containing polymers.

4. The ink composition according to claim 3, wherein the nitrogen-containing polymers are all or partially polyamide resins.

5. The ink composition according to claim 2, wherein the binder resins are all or partially phenolic resins.

6. The ink composition according to claim 2, wherein the fillers are all or partially silicas.

7. The ink composition according to claim 1, further comprising at least one colorant component that does not change color in a plasma treatment atmosphere.

8. An indicator for detecting plasma treatment comprising a color-changing layer formed of the ink composition according to claim 1.

9. The indicator according to claim 8 comprising a non-color-changing layer that does not change color in the plasma treatment atmosphere.

10. The indicator according to claim 8, wherein the color-changing layer is in the form of a bar code.

11. The indicator according to claim 10, wherein the color-changing layer changes color in a plasma treatment environment to allow reading by a bar code reader, thus enabling plasma treatment management.

12. A plasma treatment package comprising a gas-permeable package and the indicator according to claim 8 on the inner surface of the package.

13. The package according to claim 12, having a transparent window in a part of the package so as to enable the indicator to be checked from the outside.

14. A plasma treatment method comprising placing one or more items to be treated in the package according to claim 12, sealing the package containing the items to be treated, and disposing the package in the plasma treatment atmosphere.

15. The treatment method according to claim 14, wherein the package is allowed to stand in the plasma treatment atmosphere until the color-changing layer of the indicator has changed color.

16. An image drawing tool comprising the ink composition according to claim 1.
